(19) United States
(12) Patent Application Publication
(10) Pub. No.: US 2009/0101947 A1
(43) Pub. Date: Apr. 23, 2009

(54) Image sensor device and fabrication method thereof

(75) Inventors: Chien-Pang Lin, Hsinchu (TW); Chin-Poh Pang, Hsinchu (TW); Wu-Chieh Liu, Keelung (TW); Shiu-Fang Yen, Yunlin (TW)

Correspondence Address: Joe McKinney Muncy, PO Box 1364, Fairfax, VA, 22038-1364, US

(73) Assignee: VisEra Technologies Company Limited

(21) Appl. No.: 11/907,793

(22) Filed: Oct. 17, 2007

(51) Int. Cl. H01L 31/062; H01L 21/00

(52) U.S. Cl. 257/292; 438/70; 257/E31.001

(57) ABSTRACT

An image sensor device is disclosed. The image sensor device comprises a substrate having a pixel array therein. A first transparent layer with a curved surface is disposed on the substrate. A micro lens array is conformally disposed on the curved surface of the first transparent layer and corresponds to the pixel array in the substrate. The invention also discloses an electronic assembly for an image sensor device and a fabrication method thereof.

### BACKGROUND OF THE INVENTION

1. Field of the Invention

The invention relates to an optoelectronic device and more particularly to a structure of an image sensor and a method for fabricating the same.

2. Description of the Related Art

As optoelectronic applications, such as digital cameras, digital video recorders, image capture capable mobile phones and monitors, become more and more popular, the demand for image sensor devices accordingly increase. An image sensor device is used for recording a change of a photo signal from an image and converting the photo signal into an electronic signal. After recording and processing the electronic signal, a digital image is generated. In general, image sensor devices can be categorized into two main types, one is charge coupled devices (CCD) and the other complementary metal oxide semiconductor (CMOS) devices.

The image sensor device typically comprises a pixel array. Each pixel includes a photosensor that produces a signal corresponding to the intensity of light impinging on the photosensor. When an image is focused on the array, signals can be employed to display a corresponding image. In conventional technology, a micro lens array equipped with a color filter array, is correspondingly disposed above the pixel array and used for focusing light onto the pixel array. The color filter array allows the pixels to collect light with specified wavelengths.

However, despite the use of the micro lens array, a large amount of incident light is not directed efficiently onto the photosensors due to the geometry of the micro lens array. The focal depth of the incident light to each photosensor is varied with the incident angle of the light (i.e. chief ray angle (CRA)). Since the light incident to the photosensors located at the vicinity of the edge of the pixel array is often inclined, a shallower focal depth is seen at the vicinity of the edge of the pixel array compared to the light incident to the photosensors located at the vicinity of the center of the pixel array. The different focal depths make the quantity of the incident light near the edge of the pixel array poorer than that near the center of the pixel array. As a result, photosensitivity of the image sensor device is reduced.

Therefore, there is a need to develop a novel structure of an image sensor device capable of increasing photosensitivity of the image sensor device.

### BRIEF SUMMARY OF THE INVENTION

A detailed description is given in the following embodiments with reference to the accompanying drawings. An image sensor device and a fabrication method thereof are provided. An embodiment of an image sensor device comprises a substrate having a pixel array therein. A first transparent layer with a curved surface is disposed on the substrate. A micro lens array is conformally disposed on the curved surface of the first transparent layer and corresponds to the pixel array in the substrate.

An embodiment of a method for fabricating an image sensor device comprises providing a substrate having a pixel array therein. A first transparent layer with a curved surface is formed on the substrate. A micro lens array is conformally formed on the curved surface of the first transparent layer and corresponds to the pixel array in the substrate.

### BRIEF DESCRIPTION OF DRAWINGS

The invention can be more fully understood by reading the subsequent detailed description and examples with references made to the accompanying drawings, wherein:

FIGS. 1A to 1E are cross sections of an exemplary embodiment of a method for fabricating an image sensor device according to the invention;

FIGS. 2A to 2C are cross sections of an exemplary embodiment of a method for forming a layer with a curved surface for an image sensor device according to the invention;

FIGS. 3A to 3C are cross sections of an exemplary embodiment of a method for forming a layer with a curved surface for an image sensor device according to the invention;

FIG. 4 is a partial cross section of an exemplary embodiment of an image sensor device according to the invention; and

FIG. 5 is a cross section of an exemplary embodiment of an image sensor module according to the invention.

### DETAILED DESCRIPTION OF INVENTION

The following description is of the best-contemplated mode of carrying out the invention. This description is provided for the purpose of illustrating the general principles of the invention and should not be taken in a limiting sense. The scope of the invention is best determined by reference to the appended claims.

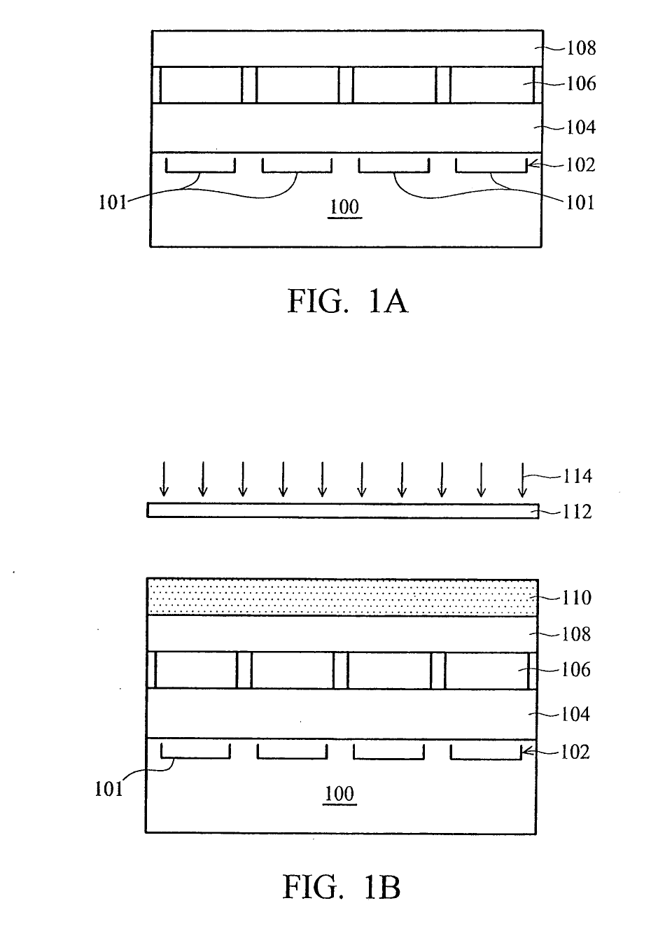

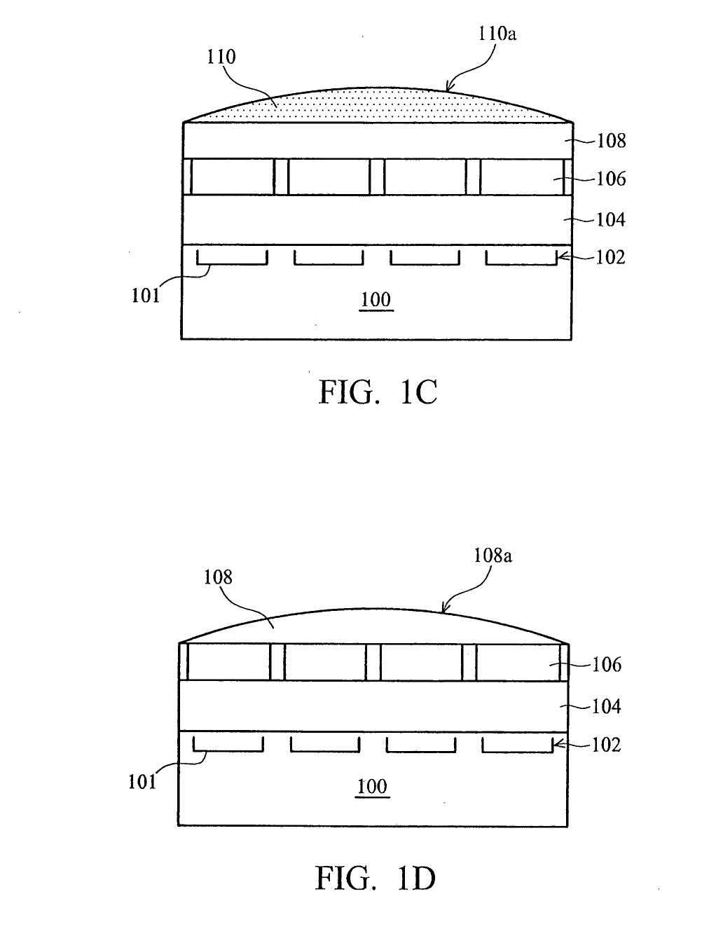

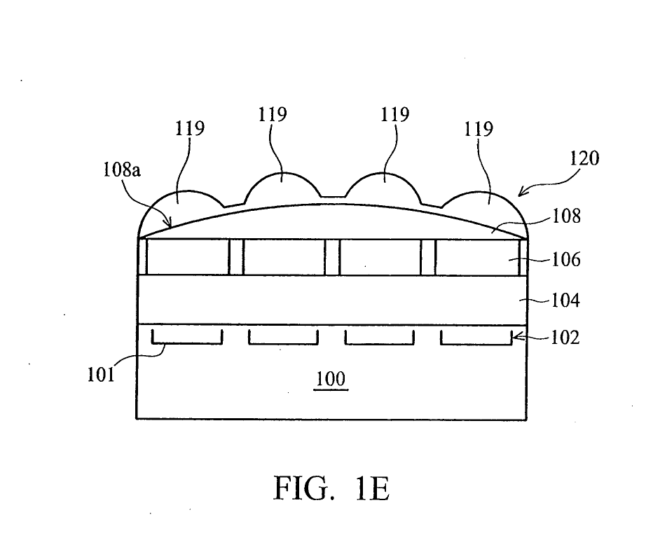

FIG. 1E illustrates an exemplary embodiment of an image sensor device according to the invention. The image sensor device comprises a substrate 100, such as a semiconductor substrate, having a pixel array 102 therein. Isolation regions (not shown) may be formed in the substrate 100 to define active regions for arrangement of the pixel array 102. Each unit pixel in the pixel array 102 includes a corresponding photosensor 101 for converting a photo signal from an incident light (not shown) into an electronic signal.

A transparent layer 104 is disposed on the substrate 100. The transparent layer 104 may comprise a single layer or a multi-layer structure. In the embodiment, the transparent layer comprises an interlayer dielectric (ILD) layer and an overlying passivation or planarization layer. In order to simply the diagram, only a flat transparent layer 104 is depicted.

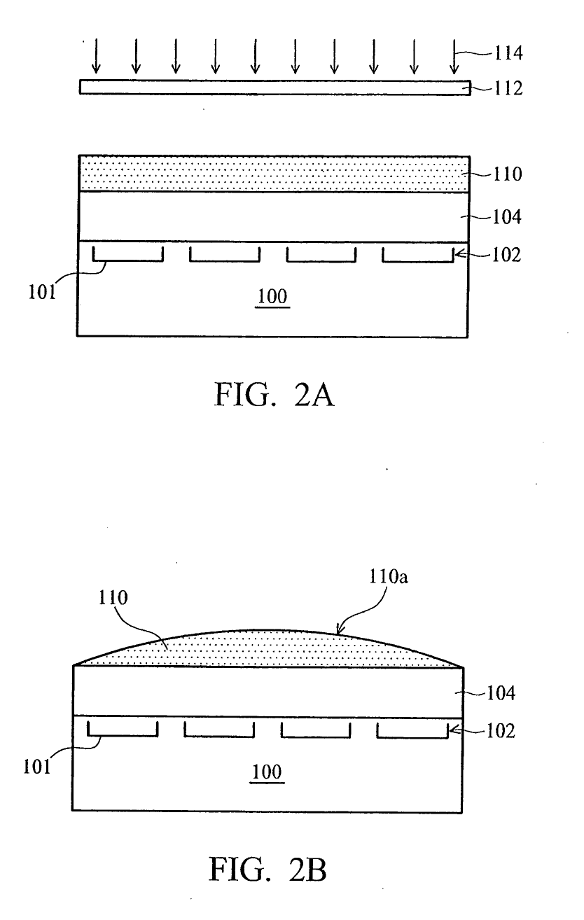

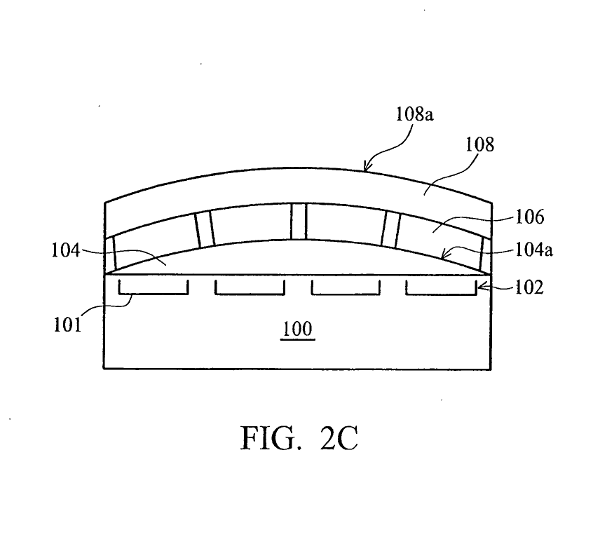

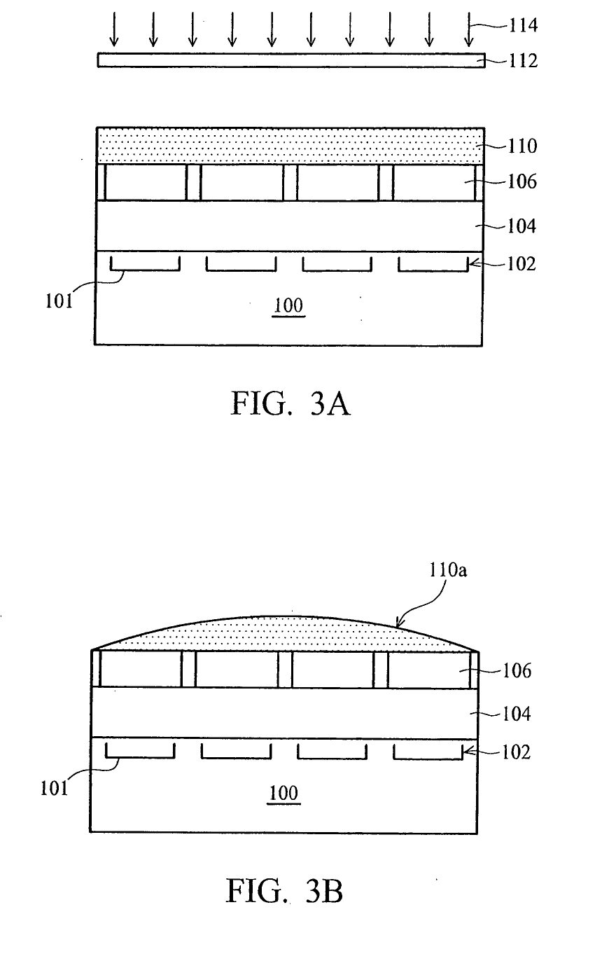

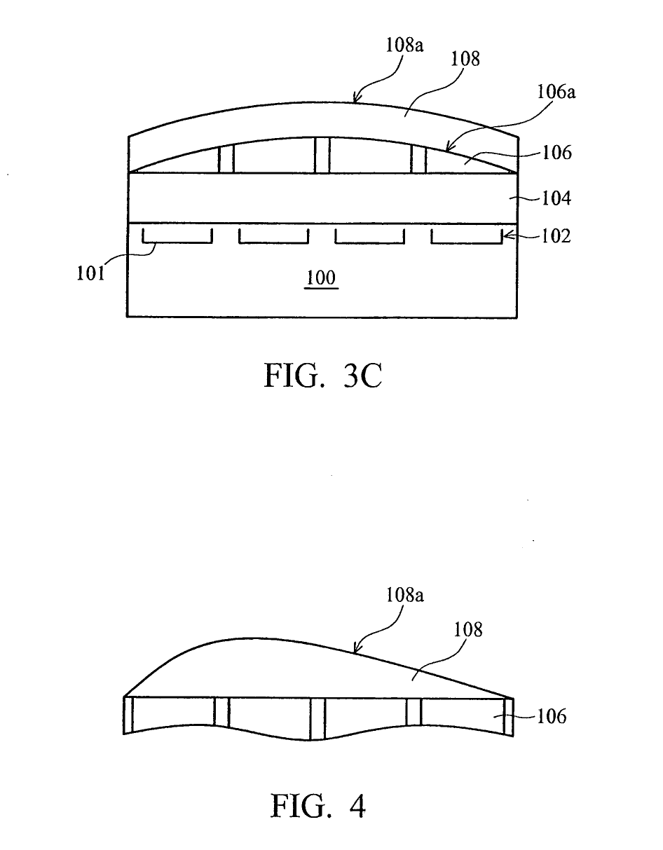

A color filter layer 106 having red, green and blue color filters is disposed on the transparent layer 104. Another transparent layer 108 comprising silicon oxide, silicon oxide or combinations thereof covers the color filter layer 106 for protection of the color filter layer 106. In the embodiment, the transparent layer 108 has a curved surface 108a for compensating the focal depth shift of the subsequent micro lenses at different chief ray angle (CRA). For example, the transparent layer 108 has a piano-convex shape and the curved surface 108a thereof is symmetric convex, as shown in FIG. 1E. In another embodiment, the curved surface 108a of the transparent layer 108 is an asymmetric convex, as shown in FIG. 4. Moreover, in other embodiments, the curved surface 108a is formed of a transparent layer 104 with a curved surface 104a, as shown in FIG. 2C, or formed by a color filter layer 106 with a curved surface 106a, as shown in FIG. 3C. Since the color filter layer 106 and the transparent layer 108 are successively and conformally disposed on the transparent layer 104 with a curved surface 104a, the curved surface 108a is substantially the same as the surfaces 106a and/or 104a.

FIGS. 1A to 1E are cross sections of an exemplary embodiment of a method for fabricating an image sensor device according to the invention. Referring to FIG. 1A, a substrate 100 having a pixel array 102 therein is provided. The substrate 100, such as a silicon substrate or other semiconductor substrates, may contain a variety of elements, including, for example, transistors, resistors, and other semiconductor elements well known in the art. In order to simplify the diagram, a variety of elements is not depicted. Moreover, isolation regions (not shown) may be formed in the substrate 100 to define active regions for arrangement of the pixel array 102. Each active region (i.e. unit pixel) includes a corresponding photosensor 101 for converting a photo signal from an incident light (not shown) into an electronic signal. The photosensors 101 may comprise photodiodes, phototransistors or other photosensors well known in the art.

A transparent layer 104 is formed on the substrate 100. In the embodiment, the transparent layer comprises an ILD layer and an overlying passivation or planarization layer. The ILD layer may be formed by chemical vapor deposition (CVD), low pressure chemical vapor deposition (LPCVD), plasma enhanced chemical vapor deposition (PECVD), high density plasma chemical vapor deposition (HIDPCVD) or other deposition processes well known in the art and may comprise silicon oxide or low k material, such as fluorinated silicate glass (FSG), carbon doped oxide, methyl silsesquioxane (MSQ), hydrogen silsesquioxane (HSQ), or fluorine tetra-ethyl-orthosilicate (FTEOS). Moreover, the passivation or planarization layer may comprise silicon nitride (e.g., SiN, Si₃N₄), silicon oxynitride (e.g., SiON), silicon carbide (e.g., SiC), silicon oxycarbide (e.g., SiOC), or combinations thereof. Additionally, metal interconnections (not shown) may be formed in the ILD layer. In order to simply the diagram, only a fat transparent layer 104 is depicted.

A color filter layer 106 having red, green and blue color filters is formed on the transparent layer 104 by, for example, photolithography, such that each color filter can correspond to each unit pixel or photosensor 101.

Next, a transparent layer 108 is formed on the color filter layer 106 for protection of the color filter layer 106. The transparent layer 108 may be forned by CVD, LPCVD, PECVD, HDPCVD or other deposition processes well known in the art and may comprise silicon oxide, silicon oxide or combinations thereof.

Referring to FIG. 1B, a photo sensitivity layer 110, such as a positive photoresist layer, is coated on the transparent layer 108. Thereafter, an exposure process 114, for example, I-line exposure process, is performed on the photoresist layer 110 using a gray level mask 112. Typically, the gray level mask 112 has a grating structure to provide different light intensities after light passing through thereof. Accordingly, in the embodiment, the gray level mask 112 can be designed with a desired grating structure, such that the photoresist layer 110 has different thicknesses at different portions to form a curved surface 110a after exposure and development are performed. For example, the central portion of the photoresist layer 110 is thicker than that of the peripheral portion, such that the curved surface 110a of the photoresist layer 110 is symmetric convex, as shown in FIG. 1C.

Referring to FIGS. 1C and 1D, after development, the photoresist layer 110 with the curved surface 110a and the underlying transparent layer 108 are successively etched by, for example, dry etching, to remove the photoresist layer 110 while leaving the transparent layer 108 with a curved surface 108a substantially the same as the curved surface 110a of the photoresist layer 110. In the embodiment, the transparent layer 108 has a piano-convex shape and the curved surface 108a thereof is a symmetric convex. In another embodiment, the curved surface 110a of the photoresist layer 110 may be an asymmetric convex, such that the curved surface 108a of the transparent layer 108 is an asymmetric convex, as shown in FIG. 4. Note that although the left side of the transparent layer 108 shown in FIG. 4 is thicker than the right side thereof, the right side of the transparent layer 108 may also be thicker than the left side thereof in other embodiments.

Referring to FIG. 1E, a micro lens array 120 including a plurality of dome-type micro lenses 119 is conformally formed on the curved surface 108a of the transparent layer 108, in which the plurality of dome-type micro lens 119 in the micro lens array 120 corresponds to the photosensors 101 in the pixel array 102. The micro lens array 120 can be formed by coating a lens resin material (not shown) on the transparent layer 108. Then, the lens resin material is patterned by photolithography so as to be located in the position above the corresponding photosensor 101. Then, thermal flow process is performed on the patterned lens resin material, thereby forming the dome-type micro lens 119 by surface tension.

FIGS. 2A to 2C are cross sections of an exemplary embodiment of a method for forming a transparent layer with a curved surface for an image sensor device according to the invention. The elements in FIGS. 2A to 2C that are the same as those in FIGS. 1A to 1E are labeled with the same reference numbers as in FIGS. 1A to 1E and are not described again for brevity. Referring to FIG. 2A, a photoresist layer 110 is coated on a transparent layer 104 prior to formation of a color filter layer. Thereafter, an exposure process 114 is performed on the photoresist layer 110 using a gray level mask 112.

Referring to FIG. 2B, after development is performed, the photoresist layer 110 with a curved surface 110a is formed.

Referring to FIG. 2C, the photoresist layer 110 with the curved surface 110a and the underlying transparent layer 104 are successively etched to remove the photoresist layer 110 while leaving the transparent layer 104 with a curved surface 104a substantially the same as the curved surface 110a of the photoresist layer 110. Thereafter, a color filter layer 106 and a transparent layer 108 are successively and conformally formed on the curved surface 104a of the transparent layer 104, such that the color filter layer 106 and the transparent layer 108 have curved surfaces 106a and 108a, respectively, substantially the same as the curved surface 104a of the transparent layer 104.

FIGS. 3A to 3C are cross sections of an exemplary embodiment of a method for forming a layer with a curved surface for an image sensor device according to the invention. The elements in FIGS. 3A to 3C that are the same as those in FIGS. 1A to 1E are labeled with the same reference numbers as in FIGS. 1A to 1E and are not described again for brevity. Referring to FIG. 3A, a photoresist layer 110 is coated on a color filter layer 106 prior to formation of a transparent layer. Thereafter, an exposure process 114 is performed on the photoresist layer 110 using a gray level mask 112.

Referring to FIG. 3B, after development is performed, the photoresist layer 110 with a curved surface 110a is formed.

Referring to FIG. 3C, the photoresist layer 110 with the curved surface 110a and the underlying color filter layer 106 are successively etched to remove the photoresist layer 110 while leaving the color filter layer 106 with a curved surface 106a substantially the same as the curved surface 110a of the photoresist layer 110. Thereafter, a transparent layer 108 is conformally formed on the curved surface 106a of the color filter layer 106, such that the transparent layer 108 has a curved surface 108a substantially the same as the curved surface 106a of the color filter layer 106.

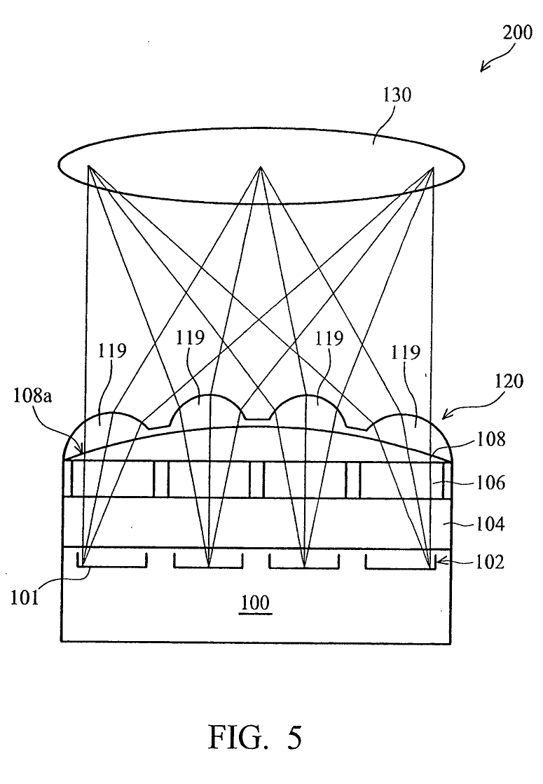

FIG. 5 is a cross section of an exemplary embodiment of an image sensor module according to the invention. The image sensor module 200 comprises an image sensor device shown in FIG. 1E and a module lens 130 disposed above the image sensor device. After incident light (not shown) passes through the module lens 130, the light is spread at a wider angle. That is, the CRA at the peripheral of the micro lenses (i.e. at the vicinity of the edge of the pixel array 102) is larger than that at the central micro lenses (i.e. at the vicinity of the center of the pixel array 102). As a result, the focal depth at peripheral micro lenses is shallower than that at the central micro lenses. Consequently, photosensitivity of the image sensor device is reduced because the light passing through the peripheral micro lenses cannot be properly focused toward the corresponding photosensors.

According to the embodiment, however, since the micro lens array 102 is directly on the curved surface 108a of the transparent layer 108, the focal depth of the light at the peripheral micro lenses can be extended so as to be properly focused toward the corresponding photosensors. Accordingly, the different focal depths at different CRA can be adjusted to substantially uniform focal depths to allow the incident light at different CRA be properly focused toward the corresponding photosensors, thereby increasing photosensitivity of the image sensor device.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An image sensor device, comprising:
a substrate having a pixel array therein;
a first transparent layer with a curved surface disposed on the substrate; and
a micro lens array conformally disposed on the curved surface of the first transparent layer and corresponding to the pixel array in the substrate.

2. The image sensor device as claimed in claim 1, further comprising a color filter layer interposed between the substrate and the first transparent layer.

3. The image sensor device as claimed in claim 2, wherein the color filter layer has a curved surface substantially the same as the curved surface of the first transparent layer.

4. The image sensor device as claimed in claim 2, further comprising a second transparent layer interposed between the substrate and the color filter layer.

5. The image sensor device as claimed in claim 4, wherein the color filter layer and the second transparent layer have a curved surface, respectively, substantially the same as the curved surface of the first transparent layer.

6. The image sensor device as claimed in claim 4, wherein the second transparent layer comprises silicon oxide, silicon nitride, or combinations thereof.

7. The image sensor device as claimed in claim 1, wherein the first transparent layer comprises silicon oxide, silicon nitride, or combinations thereof.

8. The image sensor device as claimed in claim 1, wherein the curved surface of the first transparent layer is a symmetric or asymmetric convex.

9. The image sensor device as claimed in claim 1, wherein the first transparent layer has a piano-convex shape.

10. A method for fabricating an image sensor device, comprising:
providing a substrate having a pixel array therein;
forming a first transparent layer with a curved surface on the substrate; and
conformally forming a micro lens array on the curved surface of the first transparent layer and corresponding to the pixel array in the substrate.

11. The method as claimed in claim 10, further forming a color filter layer between the substrate and the first transparent layer.

12. The method as claimed in claim 11, wherein the formation of the first transparent layer with the curved surface comprises:
forming a photoresist layer with a curved surface on the color filter layer using a gray level mask;
successively etching the photoresist layer and the underlying color filter layer to remove the photoresist layer while leaving the color filter layer with a curved surface; and
conformally forming the first transparent layer on the curved surface of the color filter layer.

13. The method as claimed in claim 11, further forming a second transparent layer between the substrate and the color filter layer.

14. The method as claimed in claim 13, wherein the formation of the first transparent layer with the curved surface comprises:
forming a photoresist layer with a curved surface on the second transparent layer using a gray level mask;
successively etching the photoresist layer and the underlying second transparent layer to remove the photoresist layer while leaving the second transparent layer with a curved surface; and
successively and conformally forming the color filter layer and the first transparent layer on the curved surface of the second transparent layer.

15. The method as claimed in claim 13, wherein the second transparent layer comprises silicon oxide, silicon nitride, or combinations thereof.

16. The method as claimed in claim 10, wherein the first transparent layer comprises silicon oxide, silicon nitride, or combinations thereof.

17. The method as claimed in claim 10, wherein the formation of the first transparent layer with the curved surface comprises:
forming a photoresist layer with a curved surface on the first transparent layer using a gray level mask; and
successively etching the photoresist layer and the underlying first transparent layer to remove the photoresist layer while leaving the first transparent layer with the curved surface.

18. The method as claimed in claim 10, wherein the curved surface of the first transparent layer is a symmetric or asymmetric convex.

19. The method as claimed in claim 1, wherein the first transparent layer has a piano-convex shape.
